(19) United States
(12) Patent Application Publication
(10) Pub. No.: US 2026/0215301 A1
(43) Pub. Date: Jul. 23, 2026

(54) PRINTED CIRCUIT BOARD

(71) Applicant: SAMSUNG ELECTRO-MECHANICS CO., LTD., Suwon-si (KR)

(72) Inventors: Ki Hwan Kim, Suwon-si (KR); Gopal Garg, Suwon-si (KR); Chi Won Hwang, Suwon-si (KR); Jong Eun Park, Suwon-si (KR)

(73) Assignee: SAMSUNG ELECTRO-MECHANICS CO., LTD., Suwon-si (KR)

(21) Appl. No.: 19/018,458

(22) Filed: Jan. 13, 2025

(51) Int. Cl. H01L 23/538; G02B 6/12; H01L 23/15; H01L 25/065; H01L 25/16; H05K 1/18; H10B 80/00

(52) U.S. Cl. CPC H10W 70/65; H05K 1/185; H10W 70/611; H10W 70/685; H10W 70/692; G02B 6/12; H05K 2201/10378; H10B 80/00; H10W 90/00

(57) ABSTRACT

A printed circuit board includes a plurality of insulating layers; a plurality of wiring layers respectively disposed on or in the plurality of insulating layers; a plurality of via layers respectively disposed in the plurality of insulating layers and respectively connected to at least one of the plurality of wiring layers; and an interposer embedded in the plurality of insulating layers, and including a glass layer and a redistribution layer disposed on the glass layer.

### TECHNICAL FIELD

The present disclosure relates to a printed circuit board.

### BACKGROUND

Recently, due to the chipletization of high-performance semiconductor chips, the increase in bandwidth of memory, and the increase in the number of memories to be adopted, technologies of increasing an area, increasing the number of layers, and 2.nD packaging for package substrates are required. In order to connect microcircuits of such chipletized semiconductor chips, embedded multi-die interconnect bridge (EMIB) or similar technologies may be used, but the increase in area may be difficult, assembly is impossible at fine pitches, making application difficult, and there may be a limitation, in that the chip design should be changed from the beginning to expand the pitch for application.

### SUMMARY

An aspect of the present disclosure is to provide a printed circuit board in which an interposer easily connecting microcircuits between semiconductor chips and capable of increasing an area is included.

An aspect of the present disclosure is to provide a printed circuit board capable of simplifying a process by forming such an interposer therein.

One of the various solutions proposed through the present disclosure is to manufacture an interposer forming a redistribution layer by applying a polymer material to a glass panel capable of increasing an area to form a metal pattern and a metal via, and to embed the interposer in a multilayer printed circuit board.

For example, a printed circuit board according to an example includes a plurality of insulating layers; a plurality of wiring layers respectively disposed on or in the plurality of insulating layers; a plurality of via layers respectively disposed in the plurality of insulating layers and respectively connected to at least one of the plurality of wiring layers; and an interposer embedded in the plurality of insulating layers, and including a glass layer and a redistribution layer disposed on the glass layer.

For example, a printed circuit board according to an example includes a first substrate portion including a plurality of insulating layers, and a plurality of wiring layers respectively disposed on or in the plurality of insulating layers; and a second substrate portion including a glass plate, a plurality of polymer layers stacked on the glass plate, and a plurality of metal pattern layers respectively disposed on or in the plurality of polymer layers, wherein the second substrate portion is embedded in the first substrate portion, and at least one of the plurality of metal pattern layers is electrically connected to at least one of the plurality of wiring layers.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system.

FIG. 2 is a cross-sectional view schematically illustrating an example of an interposer.

FIG. 3 is a cross-sectional view schematically illustrating an example of an interposer-embedded printed circuit board.

FIGS. 4 to 7 are cross-sectional views schematically illustrating a process of manufacturing an interposer-embedded printed circuit board.

### DETAILED DESCRIPTION

Hereinafter, the present disclosure will be described with reference to the accompanying drawings. Shapes, sizes, and the like of the elements in the drawings may be exaggerated or reduced for clarity of description.

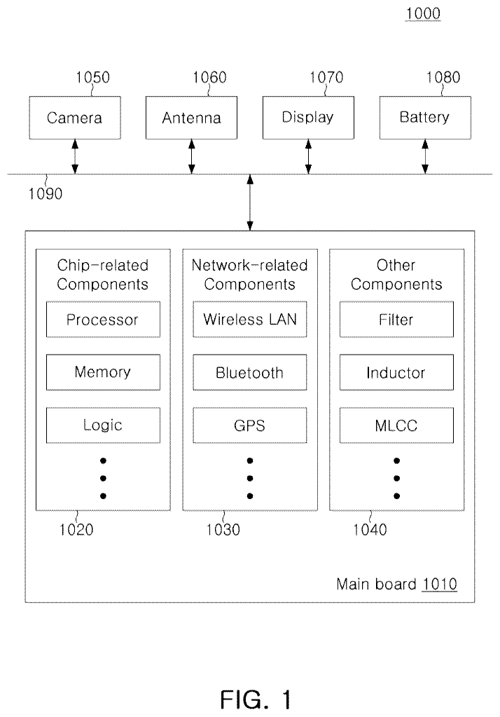

FIG. 1 is a block diagram schematically illustrating an example of an electronic device system.

Referring to the drawing, an electronic device 1000 may accommodate a main board 1010 therein. The main board 1010 may include chip related components 1020, network related components 1030, other components 1040, and the like, physically and/or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; a logic chip such as an analog-to-digital converter, an application-specific integrated circuit (ASIC), or the like; and the like. However, the chip related components 1020 are not limited thereto, but may also include other types of chip related components. In addition, the chip related components 1020 may be combined with each other. The chip related component 1020 may be in the form of a package including the above-described chip or an electronic component.

The network related components 1030 may include wireless fidelity (Wi-Fi) (Institute of Electrical and Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access +(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include components compatible with or communicating using a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 and/or the network related components 1030, described above.

Depending on a type of the electronic device 1000, the electronic device 1000 may include other components that may or may not be physically and/or electrically connected to the main board 1010. These other components may include, for example, a camera module 1050, an antenna module 1060, a display device 1070, a battery 1080, or the like. However, these other components are not limited thereto, but may also include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. These other components may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

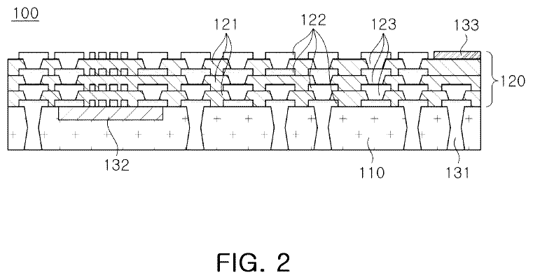

FIG. 2 is a cross-sectional view schematically illustrating an example of an interposer.

Referring to the drawing, an interposer 100 according to an example may include a glass layer 110 and a redistribution layer 120 disposed on the glass layer 110. As necessary, the interposer may further include a through-via layer 131 penetrating the glass layer 110, at least one component 132 embedded in the glass layer 110, and/or a wave guide pattern 133 formed in the redistribution layer 120. The redistribution layer 120 may include a plurality of polymer layers 121 stacked on the glass layer 110, a plurality of metal pattern layers 122 respectively disposed on or in the plurality of polymer layers 121, and a plurality of metal via layers 123 respectively disposed in the plurality of polymer layers 121 and respectively connected to at least one of the plurality of metal pattern layers 122.

In this manner, an interposer 100 according to an example may include a glass layer 110 capable of increasing an area, and may thus be easily applied to a large-area product. In addition, the glass layer 110 may have excellent rigidity, and may thus be advantageous for process warpage control. In addition, the glass layer 110 may provide a flat base surface. Therefore, since the redistribution layer 120 including a microcircuit may be easily formed on the glass layer 110, it is advantageous for interconnection between semiconductor chips. In addition, the through-via layer 131 including a through-glass-via (TGV) may be formed in the glass layer 110, and through this, electrical conduction is possible not only on an upper side but also on a lower side of the interposer 100. In addition, the glass layer 110 may have at least one component 132 embedded therein, and the at least one component 132 may include, for example, a silicon bridge or a silicon capacitor. Therefore, finer interconnections are possible, and are also useful for efficient power management. In addition, the wave guide pattern 133 may be formed in the redistribution layer 120. Therefore, optical communication is possible, and it is also easily connected to a photonic integrated circuit (PIC).

Hereinafter, components of an interposer 100 according to an example will be described in more detail with reference to the drawings.

The glass layer 110 may include glass, which may be an amorphous solid. The glass may include, for example, pure silicon dioxide (about 100% SiO₂), soda lime glass, borosilicate glass, aluminosilicate glass, and the like. However, the present disclosure is not limited thereto, and an alternative glass material, such as fluorine glass, phosphate glass, chalcogen glass, or the like, may also be used as a material. In addition, other additives may be further included to form glass having specific physical properties. These additives may include not only calcium carbonate (e.g., lime) and sodium carbonate (e.g., soda), but also magnesium, calcium, manganese, aluminum, lead, boron, iron, chromium, potassium, sulfur, and antimony, and carbonates and/or oxides of these elements and other elements. The glass layer 110 may be a layer distinct from an organic insulating material including a glass fiber (glass fiber, glass cloth, and glass fabric), such as a copper clad laminate (CCL), a prepreg (PPG), or the like. For example, the glass layer 110 may include a glass panel capable of increasing an area, such as a glass plate.

Each of the plurality of polymer layers 121 may include an insulating material. The insulating material may include a thermosetting resin such as an epoxy resin, a thermoplastic resin such as polyimide, or a material including an inorganic filler and/or an organic filler together with these resins. For example, the insulating material may be a non-photosensitive insulating material such as an Ajinomoto build-up film (ABF), but the present disclosure is not limited thereto, and other polymeric materials may be used in addition thereto. In addition, the insulating material may be a photosensitive insulating material such as a photoimageable dielectric (PID). The plurality of polymer layers 121 may include insulating materials substantially identical to each other.

Each of the plurality of metal pattern layers 122 may include a metal. The metal may include copper (Cu), aluminum (Al), silver (Ag), tin (Sn), gold (Au), nickel (Ni), lead (Pb), titanium (Ti), and/or alloys thereof, or the like. Preferably, the metal may include copper (Cu), but the present disclosure is not limited thereto. Each of the plurality of metal pattern layers 122 may perform various functions according to a design. For example, a signal pattern, a power pattern, a ground pattern, or the like may be included. Each of these patterns may have various shapes such as a line, a plane, a pad, or the like. Each of the plurality of metal pattern layers 122 may include an electroless plating layer (e.g., chemical copper) and an electrolytic plating layer (e.g., electrolytic copper). Instead of the electroless plating layer, a sputtering layer may be included, and as necessary, both the electroless plating layer and the sputtering layer may be included. The sputtering layer may be a stacked structure of a titanium (Ti) layer and a copper (Cu) layer, but the present disclosure is not limited thereto.

Each of the plurality of metal via layers 123 may include a metal. The metal may include copper (Cu), aluminum (Al), silver (Ag), tin (Sn), gold (Au), nickel (Ni), lead (Pb), titanium (Ti), and/or an alloy thereof, or the like. Preferably, the metal may include copper (Cu), but the present disclosure is not limited thereto. Each of the plurality of metal via layers 123 may include a filled via filling a via hole, but may also include a conformal via disposed along a wall surface of a via hole. The plurality of metal via layers 123 may be provided as a stacked via, and may be disposed alternately with the plurality of metal pattern layers 122. The plurality of metal via layers 123 may perform various functions according to a design. For example, a ground via, a power via, a signal via, or the like may be included. The plurality of metal via layers 123 may have a tapered shape in the same direction in the cross-section, for example, a tapered shape in which a width of an upper end portion is wider than a width of a lower end portion in the cross-section. Each of the plurality of metal via layers 123 may include an electroless plating layer (e.g., chemical copper) and an electrolytic plating layer (e.g., electrolytic copper). Instead of the electroless plating layer, a sputtering layer may be included, and as necessary, both the electroless plating layer and the sputtering layer may be included. The sputtering layer may be a stacked structure of a titanium (Ti) layer and a copper (Cu) layer, but the present disclosure is not limited thereto.

The through-via layer 131 may include a metal. The metal may include copper (Cu), aluminum (Al), silver (Ag), tin (Sn), gold (Au), nickel (Ni), lead (Pb), titanium (Ti), and/or an alloy thereof, or the like. Preferably, the metal may include copper (Cu), but the present disclosure is not limited thereto. The through-via layer 131 may include a filled VIA that fills a through-hole, and may include, for example, a through-glass-via (TGV). The through-via layer 131 may perform various functions according to a design. For example, a ground through-via, a power through-via, a signal through-via, or the like may be included. The through-via layer 131 may have a substantially hourglass shape in a cross-section, but the present disclosure is not limited thereto, and may have a substantially rectangular shape in the cross-section. In plan, the through-via may have a circular, elliptical or polygonal (e.g., rectangle, square, trapezoid, hexagon, or any other convex or non-convex polygon) shape. The through-via layer 131 may include an electroless plating layer (e.g., chemical copper) and an electrolytic plating layer (e.g., electrolytic copper). Instead of the electroless plating layer, a sputtering layer may be included, and as necessary, both the electroless plating layer and the sputtering layer may be included. The sputtering layer may be a stacked structure of a titanium (Ti) layer and a copper (Cu) layer, but the present disclosure is not limited thereto. The through-via layer 131 may be connected to at least one of the plurality of metal pattern layers 122, for example, a lowermost metal pattern layer 122.

The component 132 may be various types of electronic components, for example, a silicon bridge and/or a silicon capacitor, but the present disclosure is not limited thereto. The component 132 may be embedded on an upper side of the glass layer 110. The component 132 may be embedded in the glass layer 110 without a cavity, but the present disclosure is not limited thereto, and may be embedded in the glass layer 110 in a form disposed in a cavity of the glass layer 110. The component 132 may be connected to at least one of the plurality of metal pattern layers 122 and at least one of the plurality of metal via layers 123.

The wave guide pattern 133 may have a structure for transmitting an optical signal. The wave guide pattern 133 may be formed on an uppermost polymer layer 121, but the present disclosure is not limited thereto, and may be formed on at least one of medial polymer layers 121, as needed. The wave guide pattern 133 may be formed of various known materials such as a metal material, a semiconductor material, a dielectric material, a sealing material, or the like.

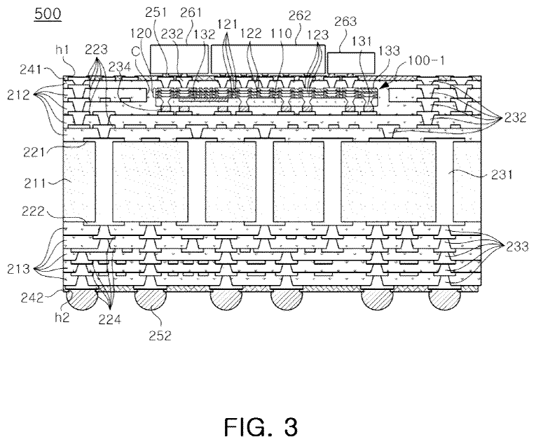

FIG. 3 is a cross-sectional view schematically illustrating an example of an interposer-embedded printed circuit board.

Referring to the drawing, an interposer-embedded printed circuit board 500 according to an example may include a plurality of insulating layers 211, 212, and 213, a plurality of wiring layers 221, 222, 223, and 224 respectively disposed on or in the plurality of insulating layers 211, 212, and 213, a plurality of via layers 231, 232, and 233 respectively disposed in the plurality of insulating layers 211, 212, and 213 and respectively connected to at least one of the plurality of wiring layers 221, 222, 223, and 224, and an interposer 100-1 embedded in the plurality of insulating layers 211, 212, and 213. As necessary, the board 500 may further include a first passivation layer 241 disposed on an upper side of the plurality of insulating layers 211, 212, and 213 and having a plurality of first openings h1, a second passivation layer 242 disposed on an lower side of the plurality of insulating layers 211, 212, and 213 and having a plurality of second openings h2, a plurality of first electrical connection metals 251 respectively disposed on the plurality of first openings h1, a plurality of second electrical connection metals 252 respectively disposed on the plurality of second openings h2, and/or a plurality of semiconductor chips 261, 262, and 263 surface-mounted on the first passivation layer 241 through the plurality of first electrical connection metals 251. In this case, a remaining configuration except for the interposer 100-1 may be a first substrate portion, and the interposer 100-1 may be a second substrate portion embedded in the first substrate portion. The interposer 100-1 may include substantially the same structure as the interposer 100 according to the above-described example.

In this manner, an interposer-embedded printed circuit board 500 according to an example may have a structure in which the interposer 100-1 is manufactured by forming the redistribution layer 120 on a panel level using the glass layer 110 having excellent numerical stability and rigidity as a base layer, and the interposer 100-1 is widely embedded in a multilayer printed circuit board, for example, in a large area. In addition, a package structure may be formed by mounting the plurality of semiconductor chips 261, 262, and 263 using this as a package substrate. In this case, an increase in area and chip-to-chip microcircuit connection are possible. In addition, since it is possible to prevent deterioration of numerical stability that may be a problem in a 2.1D package substrate or the like, it is possible to simplify a process by omitting an additional process performed during foundry or assembly and directly mounting a chip on a substrate. In addition, by directly embedding or forming a component 132 such as a silicon capacitor, a silicon bridge, or the like, and a wave guide pattern 133 in the interposer 100-1, various technologies required for next-generation semiconductors may be provided with a single interposer 100-1. In addition, it may be easily applied to a large-area substrate for servers.

Hereinafter, components of an interposer-embedded printed circuit board 500 according to an example will be described in more detail with reference to the drawings.

The interposer 100-1 may include a glass layer 110 and a redistribution layer 120 disposed on the glass layer 110. In addition, the interposer 100-1 may further include a through-via layer 131 penetrating the glass layer 110, at least one component 132 embedded in the glass layer 110, and/or a wave guide pattern 133 formed in the redistribution layer 120. The redistribution layer 120 may include a plurality of polymer layers 121 stacked on the glass layer 110, a plurality of metal pattern layers 122 respectively disposed on or in the plurality of polymer layers 121, and a plurality of metal via layers 123 respectively disposed in the plurality of polymer layers 121 and respectively connected to at least one of the plurality of metal pattern layers 122. Descriptions of the glass layer 110, the plurality of polymer layers 121, the plurality of metal pattern layers 122, the plurality of metal via layers 123, the through-via layer 131, the component 132, the wave guide pattern 133, or the like may be substantially the same as that described above, and therefore, a redundant description thereof will be omitted.

The plurality of insulating layers 211, 212, and 213 may include a core insulating layer 211, a plurality of first build-up insulating layers 212 stacked on an upper surface of the core insulating layer 211, and a plurality of second build-up insulating layers 213 stacked on a lower surface of the core insulating layer 211. The interposer 100-1 may be embedded in the plurality of first build-up insulating layers 212. For example, at least one first build-up insulating layer 212 among the plurality of first build-up insulating layers 212 may have a cavity C. The interposer 100-1 may be disposed in the cavity C. At least one different first build-up insulating layer 212 among the plurality of first build-up insulating layers 212 may cover at least a portion of the interposer 100-1. The at least one different first build-up insulating layer 212 among the plurality of first build-up insulating layers 212 may fill at least a portion of the cavity C.

The core insulating layer 211 may include an organic insulation material. The organic insulation material may include a thermosetting resin such as an epoxy resin, a thermoplastic resin such as polyimide, or an inorganic filler, an organic filler, and/or a glass fiber (glass fiber, glass cloth, and glass fabric) together with the resins. For example, the organic insulation material may be, but is not limited to, a copper clad laminate (CCL), a prepreg (PPG), or the like. A thickness of the core insulating layer 211 may be greater than a thickness of each of the plurality of first and second build-up insulating layers 212 and 213. The core insulating layer 211 may be divided into a plurality of layers, as needed.

Each of the plurality of first and second build-up insulating layers 212 and 213 may include an organic insulation material. The organic insulating material may include a thermosetting resin such as an epoxy resin, a thermoplastic resin such as polyimide, or an inorganic filler, an organic filler, and/or a glass fiber (glass fiber, glass cloth, and glass fabric) together with the resins. For example, the organic insulating material may be, but is not limited to, a prepreg (PPG), an Ajinomoto build-up film (ABF), or the like. The plurality of first and second build-up insulating layers 212 and 213 may have substantially the same material as each other, but the present disclosure is not limited thereto. The plurality of first and second build-up insulating layers 212 and 213 may have the same number of layers as each other, but the present disclosure is not limited thereto.

The plurality of wiring layers 221, 222, 223, and 224 may include a first core wiring layer 221 disposed on the upper surface of the core insulating layer 211, a second core wiring layer 222 disposed on the lower surface of the core insulating layer 211, a plurality of first build-up wiring layers 223 disposed on or in the plurality of first build-up insulating layers 212, and a plurality of second build-up wiring layers 224 disposed on or in the plurality of second build-up insulating layers 213.

Each of the first and second core wiring layers 221 and 222 may include a metal. The metal may include copper (Cu), aluminum (Al), silver (Ag), tin (Sn), gold (Au), nickel (Ni), lead (Pb), titanium (Ti), and/or alloys thereof, or the like. Preferably, the metal may include copper (Cu), but the present disclosure is not limited thereto. The first and second core wiring layers 221 and 222 may perform various functions according to a design. For example, a signal pattern, a power pattern, a ground pattern, or the like may be included. Each of these patterns may have various shapes such as a line, a plane, a pad, or the like. The first and second core wiring layers 221 and 222 may include a seed layer and a plating layer, respectively. The seed layer may be formed by electroless plating (or chemical copper), and may be formed by a sputtering process, as necessary. Alternatively, both thereof may be used. The plating layer may be formed by electrolytic plating (or electrolytic copper). As necessary, a copper foil may be further included.

Each of the plurality of first and second build-up wiring layers 223 and 224 may include a metal. The metal may include copper (Cu), aluminum (Al), silver (Ag), tin (Sn), gold (Au), nickel (Ni), lead (Pb), titanium (Ti), and/or alloys thereof, or the like. Preferably, the metal may include copper (Cu), but the present disclosure is not limited thereto. Each of the plurality of first and second build-up wiring layers 223 and 224 may perform various functions according to a design. For example, a signal pattern, a power pattern, a ground pattern, or the like may be included. Each of these patterns may have various shapes such as a line, a plane, a pad, or the like. The plurality of first and second build-up wiring layers 223 and 224 may include a seed layer and a plating layer, respectively. The seed layer may be formed by electroless plating (or chemical copper), and may be formed by a sputtering process, as necessary. Alternatively, both thereof may be used. The plating layer may be formed by electrolytic plating (or electrolytic copper). As necessary, a copper foil may be further included.

An average pitch of at least one pattern of the plurality of metal pattern layers 122 may be smaller than an average pitch of at least one wiring of the plurality of wiring layers 221, 222, 223, and 224. Preferably, an average pitch of a pattern of each of the plurality of metal pattern layers 122 may be smaller than an average pitch of wiring of each of the plurality of wiring layers 221, 222, 223, and 224. In this case, the pitch may be a value obtained by adding ½ of a line width of each of adjacent patterns (or wirings) and a gap between the adjacent patterns (or wirings). In addition, the average pitch may be an average value of pitches measured at five arbitrary points, based on a cross-section of the printed circuit board. From a similar viewpoint, an average insulating distance between at least two adjacent layers among the plurality of metal pattern layers 122 may be smaller than an average insulating distance between two adjacent layers among the plurality of wiring layers 221, 222, 223, and 224. In this case, the insulating distance may be a separation distance between the adjacent patterns (or wirings). Additionally, the average insulating distance may be an average value of insulating distances measured at five arbitrary points, based on a cross-section of the printed circuit board. For example, a second substrate portion may include a higher density circuit than a first substrate portion.

The plurality of via layers 231, 232, and 233 may include a core via layer 231 connecting the first and second core wiring layers 221 and 222 to each other in the core insulating layer 211, a plurality of first build-up via layers 232 connecting the plurality of first build-up wiring layers 223, the interposer 100-1, and the first core wiring layer 221 to each other in the plurality of first build-up insulating layers 212, and a plurality of second build-up via layers 233 connecting the plurality of second build-up wiring layers 224 and the second core wiring layer 222 to each other in the plurality of second build-up insulating layers 213.

The core via layer 231 may include a metal. The metal may include copper (Cu), aluminum (Al), silver (Ag), tin (Sn), gold (Au), nickel (Ni), lead (Pb), titanium (Ti), and/or alloys thereof, or the like. Preferably, the metal may include copper (Cu), but the present disclosure is not limited thereto. The core via layer 231 may include a plurality of through-vias penetrating between the upper and lower surfaces of the core insulating layer 211, thereby providing an electrical connection path in the core insulating layer 211. Each of the plurality of through-vias may perform various functions according to a design. For example, a signal via, a power via, a ground via, or the like may be included. The core via layer 231 may include a seed layer and a plating layer. The seed layer may be formed by electroless plating (or chemical copper), and may be formed by a sputtering process, as necessary. Alternatively, both thereof may be used. The plating layer may be formed by electrolytic plating (or electrolytic copper).

Each of the plurality of first and second build-up via layers 232 and 233 may include a metal. The metal may include copper (Cu), aluminum (Al), silver (Ag), tin (Sn), gold (Au), nickel (Ni), lead (Pb), titanium (Ti), and/or alloys thereof, or the like. Preferably, the metal may include copper (Cu), but the present disclosure is not limited thereto. Each of the plurality of first and second build-up via layers 232 and 233 may include a plurality of connection vias penetrating at least a portion of each of the plurality of first and second build-up insulating layers 212 and 213, thereby providing an electrical connection path in each of the plurality of first and second build-up insulating layers 212 and 213. Each of the plurality of connection vias may perform various functions according to a design. For example, a signal via, a power via, a ground via, or the like may be included. Each of the plurality of connection vias may include a filled via in which a via hole is filled with a metal, but may also include a conformal via in which metal is disposed along a wall surface of a via hole. Each of the plurality of connection vias may have a tapered shape in cross-section. For example, each of the plurality of connection vias of the plurality of first build-up via layers 232 may have a tapered shape in which a width of an upper end portion is wider than a width of a lower end portion in cross-section. In addition, each of the plurality of connection vias of the plurality of second build-up via layers 233 may have a tapered shape in which a width of an upper end portion is wider than a width of a lower end portion in cross-section. The plurality of first and second build-up via layers 232 and 233 may include the seed layers and the plating layers included in the plurality of first and second wiring layers 224 and 225, in the same manner, but the present disclosure is not limited thereto.

Any one first build-up wiring layer 223 disposed on a higher level than the interposer 100-1, among the plurality of first build-up wiring layers 223, may be connected to one of the plurality of metal pattern layers 122 of the interposer 100-1, for example, an uppermost metal pattern layer 122, through any one first build-up via layer 232 disposed on a higher level than the interposer 100-1, among the plurality of first build-up via layers 232. Any one second build-up wiring layer 224 disposed on a lower level than the interposer 100-1, among the plurality of second build-up wiring layers 224, may be connected to the through-via layer 131 of the interposer 100-1 through a connecting member 234. The connecting member 234 may include various kinds of conductive materials, and may include, for example, a solder bump or a conductive film, but the present disclosure is not limited thereto. The conductive film may be an anisotropic conductive film (ACF) or an unclad conductive film (UCF), but the present disclosure is not limited thereto. The connecting member 234 may be provided in plural, and may be respectively connected to a through-glass-via (TGV) of the through-via layer 131.

The first passivation layer 241 may be disposed on an upper side of the plurality of first build-up insulating layers 212 to cover at least a portion of an uppermost first build-up wiring layer 223 among the plurality of first build-up wiring layers 223. The first passivation layer 241 may have the plurality of first openings h1 respectively exposing at least a different portion of the uppermost first build-up wiring layer 223. The second passivation layer 242 may be disposed on a lower side of the plurality of second build-up insulating layers 213 to cover at least a portion of a lowermost second build-up wiring layer 224 among the plurality of second build-up wiring layers 224. The second passivation layer 242 may have the plurality of second openings h2 respectively exposing at least a different portion of the lowermost second build-up wiring layers 224. The first and second passivation layers 241 and 242 may include an organic insulating material, respectively. The organic insulating material may include a thermosetting resin such as an epoxy resin, a thermoplastic resin such as polyimide, or an inorganic filler, an organic filler, and/or a glass fiber (glass fiber, glass cloth, and glass fabric) together with the resins. For example, the organic insulating material may be, but is not limited to, an Ajinomoto build-up film (ABF), a solder resist (SR), or the like. The pad pattern exposed through the plurality of first and second openings h1 and h2 may be, but is not limited to, a solder mask defined (SMD) form and/or a non-solder mask defined (NSMD) form.

The plurality of first and second electrical connection metals 251 and 252 may be respectively disposed on the plurality of first and second openings h1 and h2, and may be respectively connected to at least a different exposed portion of the uppermost first build-up wiring layer 223 and at least a different exposed portion of the lowermost second build-up wiring layer 224. As necessary, the plurality of first and second electrical connection metals 251 and 252 may be disposed on the plurality of first and second openings h1 and h2 through a plurality of first and second underbump metals (not illustrated). The plurality of first and second electrical connection metals 251 and 252 may be formed of a low melting point metal, for example, a solder such as tin (Sn)-aluminum (Al)-copper (Cu), but are only illustrative, and materials thereof are not particularly limited thereto. Each of the plurality of first and second electrical connection metals 251 and 252 may be a ball, a pin, or the like. The plurality of first and second electrical connection metals 251 and 252 may be formed as a multilayer or a single layer, respectively. When formed as a multilayer, the plurality of first and second electrical connection metals 251 and 252 may include a copper pillar and a copper solder, and when formed as a single layer, the plurality of first and second electrical connection metals 251 and 252 may include a tin-silver solder, but the present disclosure is not limited thereto. The plurality of second electrical connection metals 252 may be mounted on a main board, a different substrate, or the like of an electronic device, such as an interposer-embedded printed circuit board 500.

The plurality of semiconductor chips 261, 262, and 263 may be surface-mounted on the first passivation layer 241 through the plurality of first electrical connection metals 251, and may be electrically connected to each other through the plurality of first build-up wiring layers 223, the plurality of first build-up wiring layers 223, and the interposer 100-1. Each of the plurality of semiconductor chips 261, 262, and 263 may include an integrated circuit (IC) die in which hundreds to millions of elements are integrated into a single chip. The integrated circuit may be, but is not limited to, a logic chip such as a central processor (e.g., CPU), a graphics processor (e.g., GPU), a field programmable gate array (FPGA), a digital signal processor, a cryptographic processor, a microprocessor, a microcontroller, an application processor (e.g., AP), an analog-to-digital converter, an application-specific IC (ASIC), and the like, and may of course be a memory chip such as a volatile memory (e.g., DRAM), a non-volatile memory (e.g., ROM), a flash memory, a high bandwidth memory (HBM), or the like, or another type of circuit such as a photonic integrated circuit (PIC). For example, the plurality of semiconductor chips 261, 262, and 263 may be, but are not limited to, an HBM, an ASIC, and a PIC, respectively.

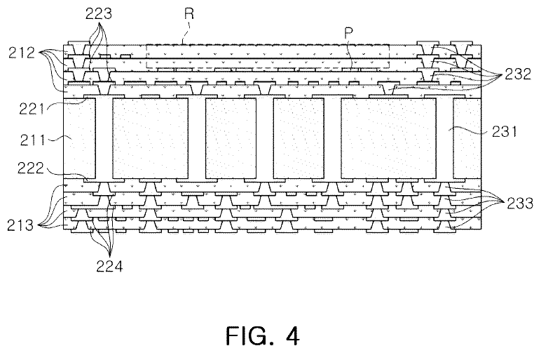

FIGS. 4 to 7 are cross-sectional views schematically illustrating a process of manufacturing an interposer-embedded printed circuit board.

Referring to FIG. 4, a core insulating layer 211 may be prepared using CCL or the like, a through-hole may be formed in the core insulating layer 211 using a CNC drill or the like, and a first and second core wiring layers 221 and 222 and a core via layer 231 may be formed in the core insulating layer 211 through a plating process. Next, a plurality of first and second build-up insulating layers 212 and 213 may be formed on the upper and lower sides of the core insulating layer 211 by lamination of ABF or PPG, respectively, and via holes may be formed in the plurality of first and second build-up insulating layers 212 and 213 by laser drilling or the like, and a plurality of first and second build-up wiring layers 223 and 224 and a plurality of first and second build-up via layers 232 and 233 may be formed in the plurality of first and second build-up insulating layers 212 and 213 by a plating process, respectively. For example, a multilayer printed circuit board may be formed by performing a build-up process on both sides of a core layer. A pattern may not be formed in a region R in which an interposer is to be embedded, and a connection pad P may be formed in a portion connected to the interposer.

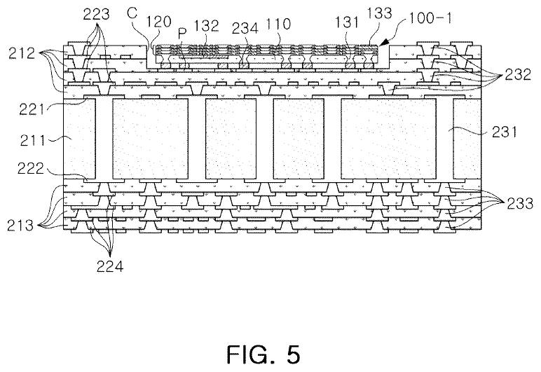

Referring to FIG. 5, a cavity C penetrating a portion of the plurality of first build-up insulating layers 212 may be formed. The cavity C may be formed using various processes such as laser processing, blast processing, or the like. The connection pad P may also function as a stopper layer for processing the cavity C. Next, an interposer 100-1, separately manufactured, may be disposed in the cavity C. For example, the interposer 100-1 may be connected to the connection pad P using a connection member 234 such as a solder bump, a conductive film, or the like. The interposer 100-1 may be manufactured by forming a through-via layer 131, a component 132, and the like on a glass layer 110 on a panel level, and then forming a redistribution layer 120, a wave guide pattern 133, and the like by a build-up process and a plating process.

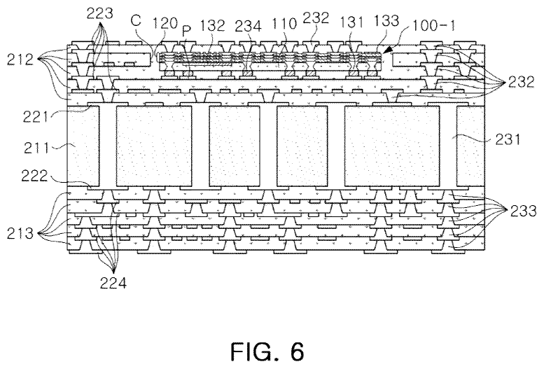

Referring to FIG. 6, first and second build-up insulating layers 212 and 213 may be additionally formed on the already formed plurality of first and second build-up insulating layers 212 and 213 by lamination of ABF or PPG, or the like, respectively. In this case, the additionally formed first build-up insulating layer 212 may fill at least a portion of the cavity C, and may embed the interposer 100-1. Next, via holes may be formed in the additionally formed first and second build-up insulating layers 212 and 213 by using a laser drill or the like, and a plating process or the like may be performed to additionally form first and second build-up wiring layers 223 and 224 and first and second build-up via layers 232 and 233. In this case, the additionally formed first build-up wiring layer 223 may be connected to a metal pattern layer 122 disposed on an uppermost side of the interposer 100-1 through an additionally formed first build-up via layer 232.

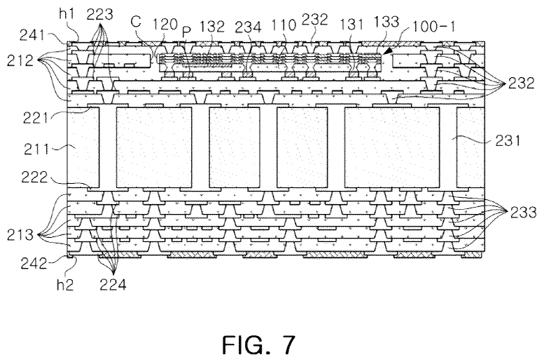

Referring to FIG. 7, first and second passivation layers 241 and 242 may be formed on the plurality of first and second build-up insulating layers 212 and 213 by lamination of ABF, coating or lamination of SR, or the like, respectively. Next, a plurality of first and second openings h1 and h2 may be formed in the first and second passivation layers 241 and 242 by laser processing or a photolithography process, respectively. Through a series of processes, an interposer-embedded printed circuit board in a form of a package substrate may be formed. Afterwards, a plurality of first and second electrical connection metals may be formed in the plurality of first and second openings h1 and h2, as needed, and a plurality of semiconductor chips may be mounted through the plurality of first electrical connection metals. In addition, a reflow process, or the like may be performed. An interposer-embedded printed circuit board in a form of a semiconductor package may be formed by a series of processes. Other descriptions may be substantially the same as those described above, and therefore, redundant descriptions thereof will be omitted.

In the present disclosure, a thickness, a width, a length, a pitch, a depth, or the like may be measured using a scanning microscope, an optical microscope, or the like, based on a cross-section of a printed circuit board that has been polished or cut. The cross-section may be a vertical cross-section or a horizontal cross-section, and each value may be measured based on a required cross-section. When a value is not constant, the value may be determined as an average value of values measured at five arbitrary points. A width of an upper and/or lower end portion of a via may be measured on a cross-section of a substrate cut along a central axis of the via in a thickness direction. A depth of the via may be measured as a distance from the upper end portion to the lower end portion in the via, in the cross-section of the substrate taken along the central axis of the via in the thickness direction.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of approximately filling. For example, the expression ‘filling’ may include a case in which some pores, voids, or the like exist.

In the present disclosure, substantially, determination may be performed by including a process error or a positional deviation occurring in a manufacturing process, an error during measurement, or the like. For example, being substantially coplanar may include not only a case in which components exist on the completely same plane, but also a case in which components exist on approximately the same plane.

In the present disclosure, the same insulating material may mean not only a case of being the completely same insulating material but also a case of including the same type of insulating material. Accordingly, a composition of the insulating material may be substantially the same, but a specific composition ratio thereof may be slightly different.

In the present disclosure, a meaning on the cross-section may refer to a cross-sectional shape when an object is cut vertically, or a cross-sectional shape when the object is viewed in a side-view. Furthermore, a meaning on a plane may refer to a planar shape when the object is horizontally cut, or a planar shape when the object is viewed in a top-view or a bottom-view.

In the present disclosure, a lower side, a lower portion, a lower surface, and the like are used to refer to a downward direction with respect to a cross-section of a drawing, and an upper side, an upper portion, an upper surface, and the like are used to refer to an opposite direction thereof. However, this defines the direction for convenience of explanation, and the scope of the rights of the claims is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first, second, and the like are used to distinguish one component from another, and do not limit the order and/or importance of the components. In some cases, a first component may be referred to as a second component without departing from the scope of rights, or similarly, the second component may be referred to as the first component.

The expression ‘example used in the present disclosure’ does not mean the same example, and is provided to explain different unique characteristics. However, the examples presented above do not preclude being implemented in combination with features of other examples. For example, even when matters described in a particular example are not described in other examples, they may be understood as explanations related to other examples unless there is an explanation contrary to or contradictory to matters in other examples.

The terms used in the present disclosure are used only to describe an example embodiment and are not intended to limit the present disclosure. In this case, singular expressions include plural expressions unless they are clearly meant differently in the context.

As one of effects of the present disclosure, a printed circuit board having an interposer embedded therein, which is easy to connect microcircuits between semiconductor chips and capable of increasing an area, may be provided.

As another of effects of the present disclosure, a printed circuit board capable of simplifying a process by forming such an interposer therein may be provided.

While example embodiments have been illustrated and described above, it will be apparent to those skilled in the art that modifications and variations could be made without departing from the scope of the present disclosure as defined by the appended claims.

What is claimed is:

1. A printed circuit board comprising:
a plurality of insulating layers;
a plurality of wiring layers respectively disposed on or in the plurality of insulating layers;
a plurality of via layers respectively disposed in the plurality of insulating layers and respectively connected to at least one of the plurality of wiring layers; and
an interposer embedded in the plurality of insulating layers, and including a glass layer and a redistribution layer disposed on the glass layer.

2. The printed circuit board of claim 1, wherein the redistribution layer comprises a plurality of polymer layers, a plurality of metal pattern layers respectively disposed on or in the plurality of polymer layers, and a plurality of metal via layers respectively disposed in the plurality of polymer layers and respectively connected to at least one of the plurality of metal pattern layers.

3. The printed circuit board of claim 2, wherein the interposer further comprises a through-via layer penetrating the glass layer and connected to at least one of the plurality of metal pattern layers.

4. The printed circuit board of claim 3, wherein any one wiring layer disposed on a higher level than the interposer, among the plurality of wiring layers, is connected to an uppermost metal pattern layer among the plurality of metal pattern layers through any one via layer disposed on a higher level than the interposer, among the plurality of via layers, and
a different wiring layer disposed on a lower level than the interposer, among the plurality of wiring layers, is connected to the through-via layer through a connecting member.

5. The printed circuit board of claim 4, wherein the connecting member comprises a solder bump or a conductive film.

6. The printed circuit board of claim 2, wherein the interposer further comprises a component embedded in the glass layer and connected to at least one of the plurality of metal pattern layers, and
the component includes at least one of a silicon bridge or a silicon capacitor.

7. The printed circuit board of claim 2, wherein the interposer further comprises a wave guide pattern disposed on or in the plurality of polymer layers.

8. The printed circuit board of claim 2, wherein an average pitch of at least one pattern of the plurality of metal pattern layers is smaller than an average pitch of at least one wiring of the plurality of wiring layers, and
an average interlayer insulating distance between at least two adjacent metal pattern layers among the plurality of metal pattern layers is smaller than an average interlayer insulating distance between at least two adjacent wiring layers among the plurality of wiring layers.

9. The printed circuit board of claim 1, wherein the plurality of insulating layers comprise a core insulating layer, and a plurality of first and second build-up insulating layers respectively stacked on upper and lower sides of the core insulating layer, and
the interposer is embedded in the plurality of first build-up insulating layers.

10. The printed circuit board of claim 9, wherein at least one first build-up insulating layer among the plurality of first build-up insulating layers has a cavity,
the interposer is disposed in the cavity, and
at least one different first build-up insulating layer among the plurality of first build-up insulating layers covers at least a portion of the interposer and fills at least a portion of the cavity.

11. The printed circuit board of claim 9, wherein the plurality of wiring layers comprise:
first and second core wiring layers respectively disposed on upper and lower surfaces of the core insulating layer;
a plurality of first build-up wiring layers respectively disposed on or in the plurality of first build-up insulating layers; and
a plurality of second build-up wiring layers respectively disposed on or in the plurality of second build-up insulating layers, and
the plurality of via layers comprise:
a core via layer connecting the first and second core wiring layers to each other in the core insulating layer;
a plurality of first build-up via layers connecting the plurality of first build-up wiring layers, the interposer, and the first core wiring layer to each other in the plurality of first build-up insulating layers; and
a plurality of second build-up via layers connecting the plurality of second build-up wiring layers and the second core wiring layer to each other in the plurality of second build-up insulating layers.

12. The printed circuit board of claim 11, further comprising:
a first passivation layer disposed on an upper side of the plurality of first build-up insulating layers, covering at least a portion of an uppermost first build-up wiring layer among the plurality of first build-up wiring layers, and having a plurality of first openings respectively exposing at least a different portion of the uppermost first build-up wiring layer; and
a second passivation layer disposed on an lower side of the plurality of second build-up insulating layers, covering at least a portion of a lowermost second build-up wiring layer among the plurality of second build-up wiring layers, and having a plurality of second openings respectively exposing at least a different portion of the lowermost second build-up wiring layer.

13. The printed circuit board of claim 12, further comprising:
a plurality of semiconductor chips respectively disposed on an upper surface of the first passivation layer;
a plurality of first electrically connecting metals respectively disposed on the plurality of first openings, respectively connected to at least different exposed portion of the uppermost first build-up wiring layer, and respectively connected to at least one of the plurality of semiconductor chips; and
a plurality of second electrically connecting metals respectively disposed on the plurality of second openings and respectively connected to at least different exposed portion of the lowermost second build-up wiring layer.

14. The printed circuit board of claim 1, wherein the glass layer comprises a glass plate.

15. A printed circuit board comprising:
a first substrate portion including a plurality of insulating layers, and a plurality of wiring layers respectively disposed on or in the plurality of insulating layers; and
a second substrate portion including a glass plate, a plurality of polymer layers stacked on the glass plate, and a plurality of metal pattern layers respectively disposed on or in the plurality of polymer layers,
wherein the second substrate portion is embedded in the first substrate portion, and
at least one of the plurality of metal pattern layers is electrically connected to at least one of the plurality of wiring layers.

16. The printed circuit board of claim 15, wherein the second substrate portion further comprises one or more selected from a through-via penetrating the glass plate and connected to at least one of the plurality of metal pattern layers, a component embedded in the glass plate and connected to at least one of the plurality of wiring layers, and a wave guide pattern disposed on or in the plurality of polymer layers.

17. An interposer embedded in a printed circuit board, comprising:
a glass layer having a through-via layer penetrating therethrough;
a redistribution layer disposed on the glass layer and comprising:
polymer layers,
metal pattern layers disposed on or in the polymer layers, at least one of the metal pattern layers being connected to the through-via layer, and
metal via layers disposed in the polymer layers and connected to at least one of the metal pattern layers; and
an electronic component embedded in the glass layer and connected to at least one of the metal pattern layers,
wherein at least one of the metal pattern layers is connected to a wiring layer of the printed circuit board.

18. The interposer of claim 17, further comprising and a wave guide pattern disposed on or in the polymer layers.

19. The interposer of claim 17, wherein the electronic component includes at least one of a silicon bridge or a silicon capacitor.

20. The interposer of claim 17, wherein the printed circuit board comprises insulating layers on which wiring layers are disposed, and via layers disposed on the insulating layers and connected to at least one of the wiring layers.
